(19) United States
(12) Patent Application Publication
(10) Pub. No.: US 2026/0360426 A1
(43) Pub. Date: Nov. 12, 2026

(54) CONTENT-ADDRESSABLE MEMORY AND WRITE CONTROL METHOD THEREOF

(71) Applicant: REALTEK SEMICONDUCTOR CORPORATION, HSINCHU (TW)

(72) Inventors: CHIH-JUNG LIU, HSINCHU (TW); I-HAO CHIANG, HSINCHU (TW)

(21) Appl. No.: 19/463,607

(22) Filed: Jan. 29, 2026

(30) Foreign Application Priority Data
May 6, 2025 (TW) 114117058

(51) Int. Cl. G11C 15/00; G11C 7/10; G11C 8/08; G11C 8/10

(52) U.S. Cl. CPC G11C 15/00; G11C 7/1096; G11C 8/08; G11C 8/10

(57) ABSTRACT

A content-addressable memory includes a boosting control circuit, a voltage boosting circuit, and a masking control circuit. The boosting control circuit is configured to generate a boost enable signal according to a level of a word line, a write enable signal, and a level of a match line. The voltage boosting circuit is configured to boost the level of the word line according to the boost enable signal. The masking control circuit is configured to adjust the level of the match line according to the write enable signal, the level of the word line, and a precharge signal. When the write enable signal and the level of the word line both indicate that a content-addressable memory unit coupled to the word line performs a write operation, the masking control circuit pulls down the level of the match line to a predetermined level.

### BACKGROUND OF THE INVENTION

### 1. Field of the Invention

The present disclosure relates to a memory device, and more particularly to a content-addressable memory that detects a level of a match line to determine a time point for boosting a level of a word line and a write control method thereof.

### 2. Description of Related Art

The content-addressable memory may perform a data comparison with data stored in the memory by inputting data to be searched, and the content-addressable memory may indicate a result of the data comparison by adjusting a level of a match line. The content-addressable memory may simultaneously perform a data reading operation and a data comparison operation, but when a write operation and a data comparison operation occur simultaneously, the write operation may cause an erroneous result of the data comparison. Therefore, in the existing art, the content-addressable memory generally adds an additional mechanism to avoid a misjudgment of the result of the data comparison caused by a write operation. However, as a word line of the content-addressable memory and a match line of the content-addressable memory are generally two metal lines disposed in parallel and adjacent in a layout design, the additional mechanism may incorrectly affect a level of the word line through electrical coupling when the additional mechanism adjusts a level of the match line, and the additional mechanism instead causes the write operation to be unable to be performed correctly.

### SUMMARY OF THE INVENTION

In some aspects, one objective of the present disclosure is to provide (but is not limited to) a content-addressable memory having an adaptive auxiliary mechanism and a write control method, so as to make an improvement to the prior art.

In some aspects, a content-addressable memory includes a boosting control circuit, a voltage boosting circuit, and a masking control circuit. The boosting control circuit is configured to generate a boost enable signal according to a level of a word line, a write enable signal, and a level of a match line. The voltage boosting circuit is configured to boost the level of the word line according to the boost enable signal. The masking control circuit is configured to adjust the level of the match line according to the write enable signal, the level of the word line, and a precharge signal. When the write enable signal and the level of the word line both indicate that a content-addressable memory unit coupled to the word line performs a write operation, the masking control circuit pulls down the level of the match line to a predetermined level.

In some aspects, a write control method that may be performed by the content-addressable memory includes the following operations: generating a boost enable signal according to a level of a word line in the content-addressable memory, a write enable signal, and a level of a match line in the content-addressable memory; boosting the level of the word line according to the boost enable signal; and adjusting the level of the match line according to the write enable signal, the level of the word line, and a precharge signal, wherein when the write enable signal and the level of the word line both indicate that a content-addressable memory unit coupled to the word line performs a write operation, the level of the match line is pulled down to a predetermined level.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 is a schematic diagram of a content-addressable memory unit according to some embodiments of the present disclosure.

FIG. 2 is a schematic diagram of a content-addressable memory according to some embodiments of the present disclosure.

FIG. 3 is a schematic diagram of the boosting control circuit of FIG. 2 according to some embodiments of the present disclosure.

FIG. 4 is a schematic diagram of the voltage boosting circuit of FIG. 2 according to some embodiments of the present disclosure.

FIG. 5 is a schematic diagram of the masking control circuit of FIG. 2 according to some embodiments of the present disclosure.

FIG. 6 is a waveform diagram of related signals of the content-addressable memory of FIG. 2 according to some embodiments of the present disclosure.

FIG. 7 is a flowchart of a write control method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may indicate a system formed with at least one circuit, and the term “circuit” may indicate an object, which is formed with one or more transistors and/or one or more active/passive elements based on a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, like elements in various figures are designated with the same reference number.

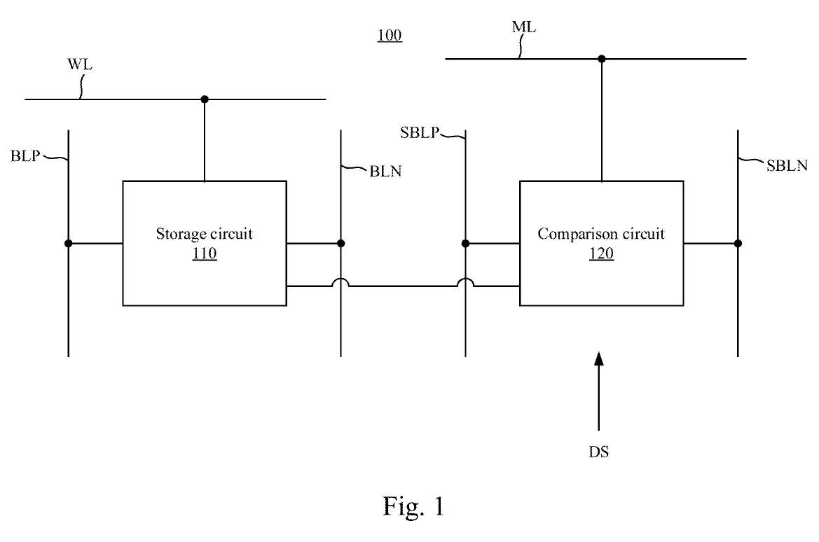

FIG. 1 is a schematic diagram of a content-addressable memory (CAM) unit 100 according to some embodiments of the present disclosure. The content-addressable memory unit 100 includes a storage circuit 110 and a comparison circuit 120. The storage circuit 110 is coupled to a word line WL, a bit line BLP, and a bit line BLN. The storage circuit 110 may be selectively enabled according to a level of the word line WL, and the storage circuit 110 may store corresponding data according to a level of the bit line BLP and a level of the bit line BLN. The comparison circuit 120 is coupled to the storage circuit 110, a search bit line SBLP, a search bit line SBLN, and a match line ML. The comparison circuit 120 may receive query data DS through the search bit line SBLP and the search bit line SBLN, and the comparison circuit 120 may compare the query data DS and data stored in the storage circuit 110. Before performing the data comparison, a level of the match line ML is precharged to a high level. When the query data DS is different from the data stored in the storage circuit 110, the level of the match line ML is pulled down to a low level (for example, a level corresponding to a logic value of 0), to indicate that a data comparison result is mismatch. Alternatively, when the query data DS is the same as the data stored in the storage circuit 110, the level of the match line ML is maintained at the high level (for example, a level corresponding to a logic value of 1), to indicate that the data comparison result is match.

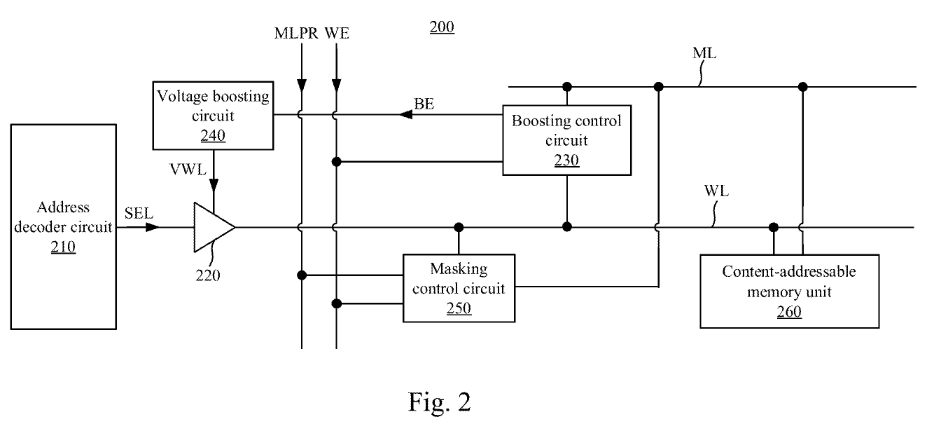

FIG. 2 is a schematic diagram of a content-addressable memory 200 according to some embodiments of the present disclosure. For clear description of embodiments of the present disclosure, FIG. 2 only shows related circuits of a memory row in the content-addressable memory 200, and FIG. 2 does not show related peripheral circuits of the content-addressable memory 200 (for example, but not limited to, a timing controller circuit, a search data register, a search data driving circuit, and the like). Arrangements of the related peripheral circuits are understood by a person having ordinary skill in the art, and thus details are omitted.

As shown in FIG. 2, the content-addressable memory 200 includes an address decoder circuit 210, a buffer circuit 220, a boosting control circuit 230, a voltage boosting circuit 240, a masking control circuit 250, a content-addressable memory unit 260, a word line WL, and a match line ML. The address decoder circuit 210 may decode a data access instruction (not shown) to generate a selection signal SEL. The buffer circuit 220 may charge the word line WL according to the selection signal SEL to increase a level of the word line WL, thereby enabling the content-addressable memory unit 260. The voltage boosting circuit 240 is configured to provide a supply voltage VWL of the buffer circuit 220, and the voltage boosting circuit 240 is configured to increase the supply voltage VWL according to a boost enable signal BE, thereby pulling up the level of the word line WL from a low level to a high level. Accordingly, when the content-addressable memory unit 260 is to perform a write operation (that is, when data is to be stored into the content-addressable memory unit 260), the voltage boosting circuit 240 may increase a conduction level of a transistor in the content-addressable memory unit 260, so that data to be written may be transmitted to the content-addressable memory unit 260 more effectively. Related operations are described later with reference to FIG. 5. The boosting control circuit 230 is configured to generate the boost enable signal BE according to the level of the word line WL, the write enable signal WE, and the level of the match line ML. The voltage boosting circuit 240 is configured to boost (e.g., raise) the level of the word line WL according to the boost enable signal BE.

The masking control circuit 250 is configured to adjust the level of the match line ML according to the write enable signal WE, the level of the word line WL, and the precharge signal MLPR. For example, before performing the data comparison, the masking control circuit 250 may precharge the match line ML to a high level. Alternatively, when data is to be written into the content-addressable memory unit 260, the masking control circuit 250 may pull down the match line ML to a low level, to avoid a misjudgment of the result of the data comparison. In other words, in some embodiments, when the write enable signal WE and the level of the word line WL both indicate that the content-addressable memory unit 260 coupled to the word line WL performs a write operation (for example, when the write enable signal WE and the level of the word line WL are high levels corresponding to a logic value of 1), the masking control circuit 250 may pull down the level of the match line ML to a predetermined level (for example, but not limited to, a level corresponding to a logic value of 0).

In some embodiments, with the arrangement of the boosting control circuit 230, the voltage boosting circuit 240 may boost the level of the word line WL according to the boost enable signal BE after the masking control circuit 250 pulls down the level of the match line ML to the predetermined level. In an actual circuit layout, the word line WL and the match line ML may be two metal lines arranged in parallel and adjacent to each other, and the write operation and the data comparison operation may occur in the same period in actual applications. In a condition in which the boosting control circuit 230 is not arranged, when a time at which the level of the match line ML is pulled down to the predetermined level through the masking control circuit 250 overlaps with a time at which the level of the word line WL is boosted to the high level through the voltage boosting circuit 240, the level of the word line WL may be unable to be boosted to an expected target level correctly, and the write operation may fail. To avoid the above problem, the boosting control circuit 230 may detect whether the level of the match line ML has been pulled down to the predetermined level through the masking control circuit 250, and the boosting control circuit 230 may switch the boost enable signal BE after the level of the match line ML has been pulled down to the predetermined level through the masking control circuit 250, thereby controlling the voltage boosting circuit 240 to boost the level of the word line WL according to the boost enable signal BE. Accordingly, the write operation of the content-addressable memory 200 may be ensured not to be affected by a data masking operation of the content-addressable memory 200 (that is, an operation of the masking control circuit 250).

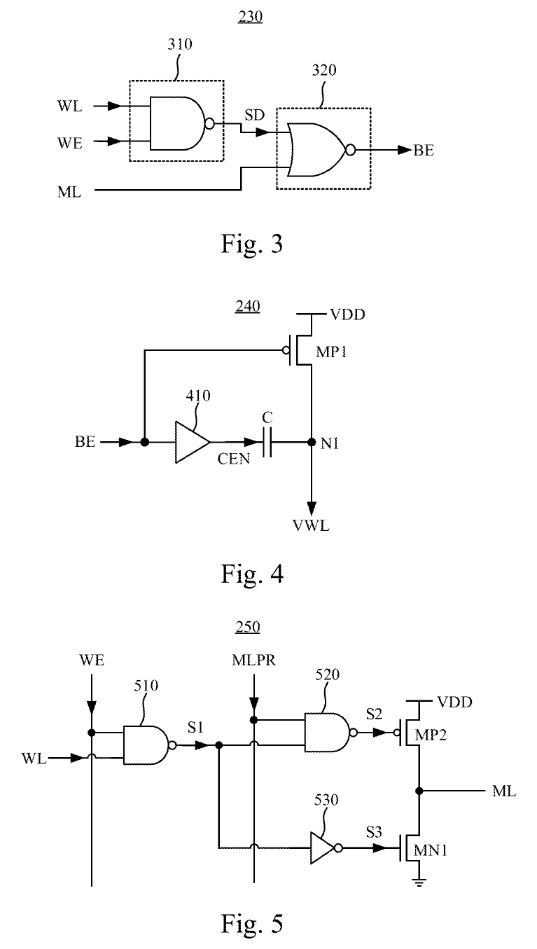

FIG. 3 is a schematic diagram of the boosting control circuit 230 of FIG. 2 according to some embodiments of the present disclosure. In some embodiments, the boosting control circuit 230 includes a write detection circuit 310 and a masking detection circuit 320. The write detection circuit 310 may be configured to detect whether the content-addressable memory unit 260 coupled to the word line WL is to perform a write operation. For example, the write detection circuit 310 may generate a detection signal SD according to the level of the word line WL and the write enable signal WE. In some embodiments, the write detection circuit 310 may be, but is not limited to, a NAND gate, and the NAND gate may generate the detection signal SD having a logic value of 0 when the level of the word line WL and a level of the write enable signal WE are high levels corresponding to a logic value of 1, thereby indicating that the content-addressable memory unit 260 is to perform the write operation.

The masking detection circuit 320 may be configured to detect whether the masking control circuit 250 has pulled down the level of the match line ML to the predetermined level. For example, the masking detection circuit 320 may generate the boost enable signal BE according to the detection signal SD and the level of the match line ML. In some embodiments, the masking detection circuit 320 may be, but is not limited to, a NOR gate, and the NOR gate may generate the boost enable signal BE having a logic value of 1 when the level of the match line ML and a level of the detection signal SD are low levels corresponding to a logic value of 0. Accordingly, in response to the boost enable signal BE, the voltage boosting circuit 240 may boost the level of the word line WL according to the boost enable signal BE after the level of the match line ML is pulled down to the predetermined level.

FIG. 4 is a schematic diagram of the voltage boosting circuit 240 of FIG. 2 according to some embodiments of the present disclosure. In some embodiments, the voltage boosting circuit 240 includes a transistor MP1, a buffer circuit 410, and a capacitor C. A first terminal (for example, a source) of the transistor MP1 receives the predetermined voltage VDD, a second terminal (for example, a drain) of the transistor MP1 is coupled to the node N1, and a control terminal (for example, a gate) of the transistor MP1 is coupled to the boosting control circuit 230 to receive the boost enable signal BE. The transistor MP1 is configured to be selectively turned on according to the boost enable signal BE, to transmit the predetermined voltage VDD to the node N1. The buffer circuit 410 is coupled to the boosting control circuit 230 to receive the boost enable signal BE, and the buffer circuit 410 is configured to generate the capacitor enable signal CEN according to the boost enable signal BE to charge the capacitor C. The capacitor C is coupled between the buffer circuit 410 and the node N1, and the capacitor C is configured to generate the supply voltage VWL (the supply voltage VWL is configured to supply power to the buffer circuit 220 of FIG. 2, thereby increasing the level of the word line WL), and the capacitor C outputs the supply voltage VWL to the buffer circuit 220 through the node N1.

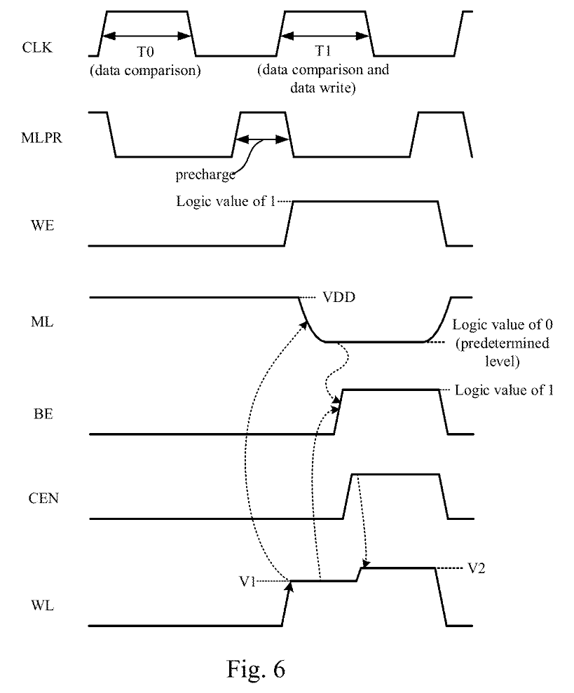

When the boost enable signal BE is a low level corresponding to a logic value of 0, the transistor MP1 is turned on to transmit the predetermined voltage VDD to the node N1, thereby pulling up a level of the supply voltage VWL to the predetermined voltage VDD. Next, when the boost enable signal BE switches to a high level corresponding to a logic value of 1, the transistor MP1 is not turned on and the transistor MP1 stops transmitting the predetermined voltage VDD to the node N1. Meanwhile, a level of the node N1 rises to a level higher than the predetermined voltage VDD through the capacitor C (for example, a level V2 of FIG. 6), to further increase the level of the supply voltage VWL, thereby pulling up the level of the word line WL.

FIG. 5 is a schematic diagram of the masking control circuit 250 of FIG. 2 according to some embodiments of the present disclosure. In some embodiments, the masking control circuit 250 includes a NAND gate 510, a NAND gate 520, an inverter 530, a transistor MP2, and a transistor MN1. The NAND gate 510 may generate a signal S1 according to the write enable signal WE and the level of the word line WL. The NAND gate 520 may generate a signal S2 according to the precharge signal MLPR and the signal S1. The inverter 530 may generate a signal S3 according to the signal S1. A first terminal of the transistor MP2 receives the predetermined voltage VDD, a second terminal of the transistor MP2 is coupled to the match line ML, and a control terminal of the transistor MP2 receives the signal S2. A first terminal (for example, a drain) of the transistor MN1 is coupled to the match line ML, a second terminal (for example, a source) of the transistor MN1 is coupled to the ground, and a control terminal (for example, a gate) of the transistor MN1 receives the signal S3.

With the above arrangement, the transistor MP2 may be selectively turned on according to the signal S2 to precharge the level of the match line ML to the predetermined voltage VDD, and the transistor MN1 may be selectively turned on according to the signal S3 to discharge the match line ML, thereby pulling down the level of the match line ML to the ground (for example, the predetermined level). For example, when the level of the word line WL is a low level corresponding to a logic value of 0, the level of the word line WL represents that the content-addressable memory unit 260 coupled to the word line WL does not perform a write operation. Under the condition, the NAND gate 510 generates the signal S1 having a logic value of 1, so that the inverter 530 generates the signal S3 having a logic value of 0, thereby turning off the transistor MN1. On the other hand, when the precharge signal MLPR is a logic value of 1, the NAND gate 520 may generate the signal S2 having a logic value of 0 according to the signal S1 and the precharge signal MLPR, thereby turning on the transistor MP2 to precharge the match line ML. Accordingly, the level of the match line ML is pulled up to the predetermined voltage VDD.

Alternatively, when the level of the word line WL and the write enable signal WE are high levels corresponding to a logic value of 1, the level of the word line WL and the write enable signal WE represent that the content-addressable memory unit 260 coupled to the word line WL is to perform a write operation. Under the condition, the NAND gate 510 generates the signal S1 having a logic value of 0, so that the inverter 530 generates the signal S3 having a logic value of 1, thereby turning on the transistor MN1. Accordingly, the match line ML may be discharged through the transistor MN1, thereby pulling down the level of the match line ML to the predetermined level. On the other hand, in response to the signal S1 having a logic value of 0, the NAND gate 520 may generate the signal S2 having a logic value of 1 to turn off the transistor MP2, thereby not precharging the match line ML. Accordingly, when the data comparison operation and the write operation occur simultaneously, misjudgment of the result of the data comparison may be avoided through the above circuit behavior.

FIG. 6 is a waveform diagram of related signals of the content-addressable memory 200 of FIG. 2 according to some embodiments of the present disclosure. In some embodiments, the system clock signal CLK in FIG. 6 may be a main clock used by an electronic system using the content-addressable memory 200, and the system clock signal CLK may be configured to define an operation phase of the content-addressable memory 200. In the period T0 of the system clock signal CLK, the content-addressable memory 200 only performs the data comparison operation. Therefore, the write enable signal WE, a boost enable signal BE, the capacitor enable signal CEN, and the level of the word line WL are low levels corresponding to a logic value of 0, and the level of the match line ML is precharged to the high level (for example, the predetermined voltage VDD) before the period T0 according to the precharge signal MLPR having the high level. In the example, a data comparison result corresponding to the period T0 is match, so the level of the match line ML is maintained at the high level.

Before the period T1 of the system clock signal CLK, the precharge signal MLPR switches to the high level, so that the masking control circuit 250 precharges the level of the match line ML to the high level again. Next, in the period T1, the content-addressable memory 200 performs the data comparison operation and the write operation simultaneously. Therefore, the write enable signal WE switches to the high level corresponding to a logic value of 1, and the word line WL is charged to a level V1 (for example, the predetermined voltage VDD) through the address decoder circuit 210 and the buffer circuit 220. In response to the write enable signal WE and the level of the word line WL, the masking control circuit 250 generates the signal S3 having a logic value of 1, to turn on the transistor MN1 and pull down the level of the match line ML to the predetermined level (for example, a low level corresponding to a logic value of 0 or a ground level) through the transistor MN1. After the level of the match line ML is pulled down to the predetermined level, the boosting control circuit 230 generates the boost enable signal BE having a logic value of 1 according to the level of the match line ML, so that the capacitor enable signal CEN also switches to a logic value of 1. Accordingly, the voltage boosting circuit 240 may further increase the supply voltage VWL, thereby pulling up the level of the word line WL from the level V1 to a higher level V2.

In the above operation process, the voltage boosting circuit 240 further pulls up the level of the word line WL to the higher level V2 after the word line WL has at least a level of a logic value of 1 (for example, the level V1). Accordingly, the voltage boosting operation may be avoided from being performed when the word line WL has the low level. Similarly, the voltage boosting circuit 240 pulls up the level of the word line WL to the level V2 after the level of the match line ML is pulled down to the predetermined level (for example, the ground level) through the masking control circuit 250. Accordingly, the data masking operation of the masking control circuit 250 may be avoided from affecting the voltage boosting operation of the voltage boosting circuit 240. In other words, with the above arrangement, control of the match line ML by the masking control circuit 250 and control of the word line WL by the voltage boosting circuit 240 may be ensured not to affect each other, thereby ensuring reliability of the write operation.

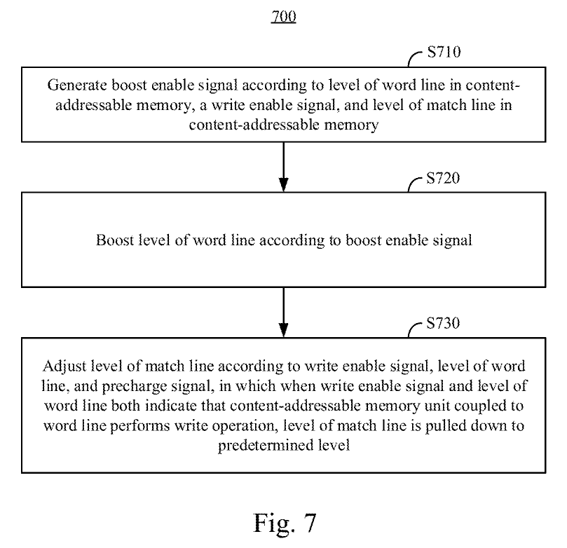

FIG. 7 is a flowchart of a write control method 700 according to some embodiments of the present disclosure. In some embodiments, the write control method 700 may be performed by, but is not limited to, the content-addressable memory 200 of FIG. 2.

In an operation S710, a boost enable signal is generated according to a level of a word line in a content-addressable memory, a write enable signal, and a level of a match line in the content-addressable memory. In an operation S720, the level of the word line is boosted according to the boost enable signal. In an operation S730, the level of the match line is adjusted according to the write enable signal, the level of the word line, and a precharge signal, in which when the write enable signal and the level of the word line both indicate that a content-addressable memory unit coupled to the word line performs a write operation, the level of the match line is pulled down to a predetermined level.

The above operations may be understood with reference to the aforementioned embodiments, and thus details are omitted. Operations in the write control method 700 are merely exemplary, and operations in the write control method 700 are not limited to being performed in the presented order. Without departing from the scope of the embodiments of the present disclosure, the operations of the write control method 700 may be appropriately added, replaced, omitted, or executed in a different order. Alternatively, the above operations may be performed simultaneously or partially simultaneously.

As described above, the content-addressable memory and the write control method of the content-addressable memory provided by some embodiments of the present disclosure may determine a time point for boosting a level of a word line by detecting a level of a match line, to avoid mutual influence between a control mechanism of the match line and a control mechanism of the word line, thereby ensuring correctness of performing a write operation.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications based on the claims of the present disclosure are all consequently viewed as being embraced by the scope of the present disclosure.

What is claimed is:

1. A content-addressable memory, comprising:
a boosting control circuit configured to generate a boost enable signal according to a level of a word line, a write enable signal, and a level of a match line;
a voltage boosting circuit configured to boost the level of the word line according to the boost enable signal; and
a masking control circuit configured to adjust the level of the match line according to the write enable signal, the level of the word line, and a precharge signal,
wherein when the write enable signal and the level of the word line both indicate that a content-addressable memory unit coupled to the word line performs a write operation, the masking control circuit pulls down the level of the match line to a predetermined level.

2. The content-addressable memory of claim 1, wherein the boosting control circuit is configured to generate a detection signal according to the level of the word line and the write enable signal, and the boosting control circuit is configured to generate the boost enable signal according to the detection signal and the level of the match line.

3. The content-addressable memory of claim 1, wherein the boosting control circuit comprises:
a write detection circuit configured to generate a detection signal according to the level of the word line and the write enable signal; and
a masking detection circuit configured to generate the boost enable signal according to the detection signal and the level of the match line.

4. The content-addressable memory of claim 1, wherein the boosting control circuit comprises:
a NAND gate configured to generate a detection signal according to the level of the word line and the write enable signal; and
a NOR gate configured to generate the boost enable signal according to the detection signal and the level of the match line.

5. The content-addressable memory of claim 1, further comprising:
an address decoder circuit configured to generate a selection signal; and
a buffer circuit configured to charge the word line according to the selection signal, to increase the level of the word line,
wherein the voltage boosting circuit is configured to increase a supply voltage of the buffer circuit according to the boost enable signal, thereby pulling up the level of the word line from a first level to a second level.

6. The content-addressable memory of claim 1, wherein the voltage boosting circuit comprises:
a transistor configured to be selectively turned on according to the boost enable signal, and transmit a predetermined voltage to a first node;
a buffer circuit configured to receive the boost enable signal; and
a capacitor coupled between an output terminal of the buffer circuit and the first node, and configured to generate a supply voltage, wherein the supply voltage is configured to pull up the level of the word line.

7. The content-addressable memory of claim 1, wherein the voltage boosting circuit is configured to boost the level of the word line according to the boost enable signal after the masking control circuit pulls down the level of the match line to the predetermined level.

8. A write control method, performed by a content-addressable memory, the write control method comprising:
generating a boost enable signal according to a level of a word line in the content-addressable memory, a write enable signal, and a level of a match line in the content-addressable memory;
boosting the level of the word line according to the boost enable signal; and
adjusting the level of the match line according to the write enable signal, the level of the word line, and a precharge signal,
wherein when the write enable signal and the level of the word line both indicate that a content-addressable memory unit coupled to the word line performs a write operation, the level of the match line is pulled down to a predetermined level.

9. The write control method of claim 8, wherein boosting the level of the word line according to the boost enable signal comprises:
boosting the level of the word line according to the write enable signal after the level of the match line is pulled down to the predetermined level.

10. The write control method of claim 8, wherein generating the boost enable signal according to the level of the word line, the write enable signal, and the level of the match line comprises:
generating a detection signal according to the level of the word line and the write enable signal; and
generating the boost enable signal according to the detection signal and the level of the match line.

11. The write control method of claim 10, wherein the detection signal is generated through a NAND gate.

12. The write control method of claim 10, wherein the boost enable signal is generated through a NOR gate.

13. The write control method of claim 8, wherein boosting the level of the word line according to the boost enable signal comprises:
selectively turning on a transistor in the content-addressable memory according to the boost enable signal, to transmit a predetermined voltage to a first node in the content-addressable memory;
receiving the boost enable signal through a buffer circuit in the content-addressable memory; and
generating a supply voltage through a capacitor in the content-addressable memory,
wherein the supply voltage is configured to pull up the level of the word line, and the capacitor is coupled between an output terminal of the buffer circuit and the first node.
